(19) United States
(12) Patent Application Publication
(10) Pub. No.: US 2016/0135282 A1
(43) Pub. Date: May 12, 2016

(54) ELECTRONIC APPARATUS

(71) Applicant: KABUSHIKI KAISHA TOSHIBA, Tokyo (JP)

(72) Inventor: Yukihiko HATA, Hamura Tokyo (JP)

(21) Appl. No.: 14/712,751

(22) Filed: May 14, 2015

Related U.S. Application Data
(60) Provisional application No. 62/076,697, filed on Nov. 7, 2014.

(51) Int. Cl. H05K 1/02; H05K 1/11

(52) U.S. Cl. CPC H05K 1/0204; H05K 1/021; H05K 1/115; H05K 1/111

(57) ABSTRACT

According to one embodiment, an electronic apparatus comprises a circuit board, a metal member and a thermal coupling member. The circuit board comprises a heat-producing component and a ground plane which comprises an exposed portion exposed on a surface of the circuit board and is thermally coupled to the heat-producing component. The metal member covers the exposed portion of the ground plane. The thermal coupling member is sandwiched between the exposed portion of the ground plane and the metal member.

### CROSS-REFERENCE TO RELATED APPLICATIONS

This application claims the benefit of U.S. Provisional Application No. 62/076,697, filed Nov. 7, 2014, the entire contents of which are incorporated herein by reference.

### FIELD

Embodiments described herein relate generally to an electronic apparatus.

### BACKGROUND

Electronic apparatuses having a thermal coupling member between heat-producing components on a circuit board and a metal member covering the heat-producing components have been provided.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing an electronic apparatus of a first embodiment;

FIG. 2 is an exemplary perspective view showing the inside of the electronic apparatus shown in FIG. 1;

FIG. 3 is an exemplary cross-sectional view showing a circuit board and a cover shown in FIG. 2;

FIG. 4 is an exemplary plan view showing a circuit board of a second embodiment;

FIG. 5 is an exemplary plan view showing a first ground plane of the circuit board shown in FIG. 4;

FIG. 6 is an exemplary cross-sectional view showing the circuit board and a cover shown in FIG. 4;

FIG. 7 is an exemplary cross-sectional view showing a thermal coupling member of a modified embodiment of the second embodiment;

FIG. 8 is an exemplary cross-sectional view showing a circuit board and a cover of a third embodiment;

FIG. 9 is an exemplary cross-sectional view showing a structure of a first modified embodiment of the third embodiment;

FIG. 10 is an exemplary cross-sectional view showing a structure of a second modified embodiment of the third embodiment;

FIG. 11 is an exemplary cross-sectional view showing a structure of a third modified embodiment of the third embodiment; and

FIG. 12 is an exemplary cross-sectional view showing an electronic apparatus of a fourth embodiment.

### DETAILED DESCRIPTION

Various embodiments will be described hereinafter with reference to the accompanying drawings.

In general, according to one embodiment, an electronic apparatus comprises a circuit board, a metal member and a thermal coupling member. The circuit board comprises a heat-producing component and a ground plane which comprises an exposed portion exposed on a surface of the circuit board and is thermally coupled to the heat-producing component. The metal member covers the exposed portion of the ground plane. The thermal coupling member is sandwiched between the exposed portion of the ground plane and the metal member.

In the specification, some elements are exemplarily expressed by a plurality of expressions. These expressions are just an example and do not deny that the above elements are expressed by other expressions. Elements not expressed by a plurality of expressions may be expressed by other expressions.

### First Embodiment

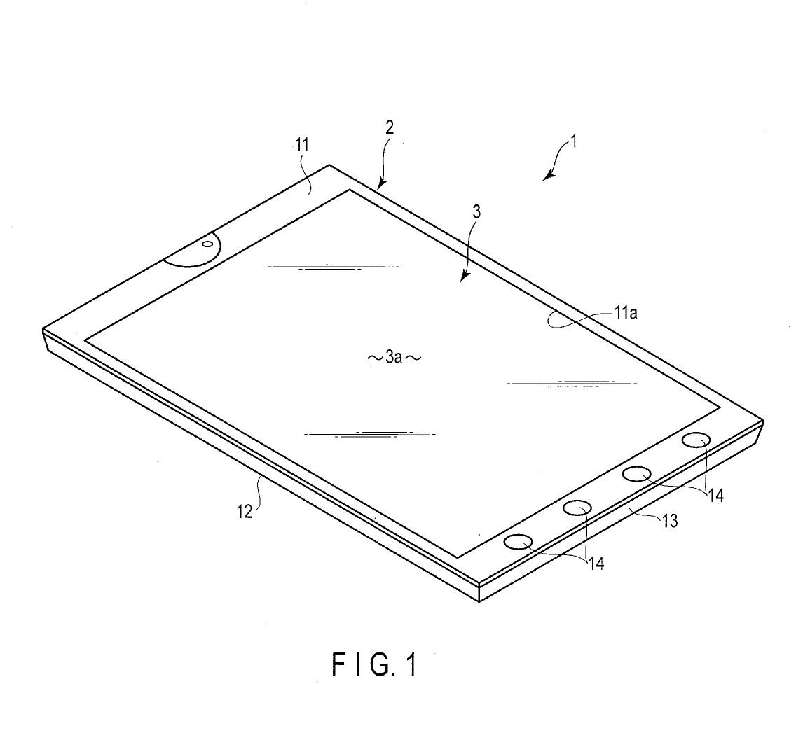

FIG. 1 to FIG. 3 show an electronic apparatus 1 of a first embodiment. The electronic apparatus 1 is, for example, a tablet (tablet portable computer). It should be noted that an electronic apparatus to which the present embodiment can be applied is not limited to the above example. The present embodiment can be applied to various electronic apparatuses such as a notebook portable computer (notebook PC), a smartphone, a wearable device, a television receiver, a game console, etc.

FIG. 1 shows an appearance of the electronic apparatus 1. The electronic apparatus 1 comprises a housing 2 and a display 3 accommodated in the housing 2. The housing 2 comprises a front wall 11 (first wall), a back wall 12 (second wall) and a peripheral wall 13 (third wall), and is formed in a flat box shape. An opening 11a through which a display screen 3a of the display 3 is exposed is provided on the front wall 11. A plurality of buttons 14 (operating portion) are also provided on the front wall 11.

The back wall 12 is positioned on the opposite side of the front wall 11 and extended approximately parallel to the front wall 11. The peripheral wall 13 is extended in a direction crossing the front wall 11 and the back wall 12, and joins a periphery of the front wall 11 and a periphery of the back wall 12.

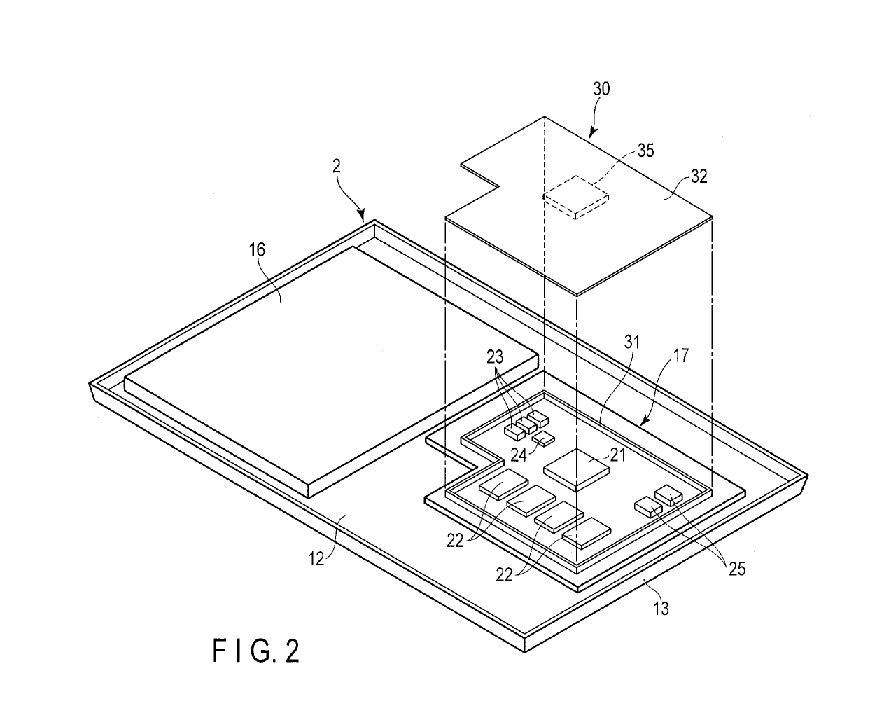

FIG. 2 shows the inside of the electronic apparatus 1. A battery 16, a circuit board 17, etc., are accommodated in the housing 2 of the electronic apparatus 1. The battery 16 supplies power to the display 3, the circuit board 17, etc. The circuit board 17 is, for example, the main board of the electronic apparatus 1, and entirely controls the electronic apparatus 1. The circuit board 17 is arranged, for example, in a position which does not overlap the battery 16 in a thickness direction of the electronic apparatus 1.

A plurality of circuit components including a central processing unit (CPU) 21, a memory 22, power supply components 23 and 24 and other electronic components 25 are mounted on the circuit board 17. The CPU 21 is an example of a component which produces heat most during operation in the circuit board 17. The CPU 21 is an example of a main heat-producing component.

The power supply components 23 and 24 produce various voltages necessary for various components of the circuit board 17 from, for example, the external power supply or the battery 16, and supplies the voltages to the components. Each of the power supply components 23 and 24 is an example of a component whose heating value during operation is lower than that of the CPU 21 but higher than that of, for example, the memory 22 and the other electronic components 25. The power supply components 23 and 24 are examples of a heat-producing component and a secondary heat-producing component, respectively.

Next, a shield structure 30 of the electronic apparatus 1 is described.

As shown in FIG. 2, the electronic apparatus 1 comprises, for example, the shield structure 30 as a measure against electromagnetic interference (EMI). The shield structure 30 comprises a frame 31 and a cover 32. The frame 31 is formed in a frame shape enclosing the CPU 21, the memory 22, the power supply components 23 and 24 and the electronic components 25 as a whole, and is attached to the surface of the circuit board 17. That is, the CPU 21, the memory 22, the power supply components 23 and 24 and the electronic components 25 are arranged inside the frame 31.

The cover 32 is attached to the frame 31 from the opposite side of the circuit board 17 to close the interior space of the frame 31. The cover 32 covers the circuit components including the CPU 21, the memory 22, the power supply components 23 and 24 and the electronic components 25 as a whole. The cover 32 is a comparatively large member which covers, for example, more than a half of the area of the circuit board 17. The cover 32 is an example of a shield metal sheet positioned between the circuit board 17 and the inner surface of the housing 2. The cover 32 may be called a spreader.

Each of the cover 32 and the frame 31 is made from metal and has superior electrical and thermal conductivity. The cover 32 and the frame 31 are electrically connected to the ground (for example, a first ground plane 41 to be described later) of the circuit board 17 and attain ground potential. The cover 32 and the frame 31 thereby reduce the influence of electromagnetic noise emitted from the outside to the circuit components and electromagnetic noise emitted from the circuit components to the outside.

Next, a radiative structure of the CPU 21 is described.

As shown in FIG. 2, a dedicated radiative structure is provided for the CPU 21 which is a main heat-producing component. More specifically, a thermal coupling member 35 is put on the top surface of the CPU 21. For example, the thermal coupling member 35 is a heat-transfer sheet (cooling sheet) and has predetermined elasticity. The thermal coupling member 35 is sandwiched between the top surface of the CPU 21 and the inner surface of the cover 32, and thermally couples the CPU 21 to the cover 32. Accordingly, at least a part of the heat from the CPU 21 is transmitted to the cover 32 via the thermal coupling member 35, diffused along the surface of the cover 32, and thereby radiated inside the housing 2 from the cover 32.

Next, a radiative structure of the power supply components 23 and 24 is described. This radiative structure can be applied to components other than the power supply components 23 and 24. Therefore, the power supply components 23 and 24 are hereinafter referred to as heat-producing components 23 and 24.

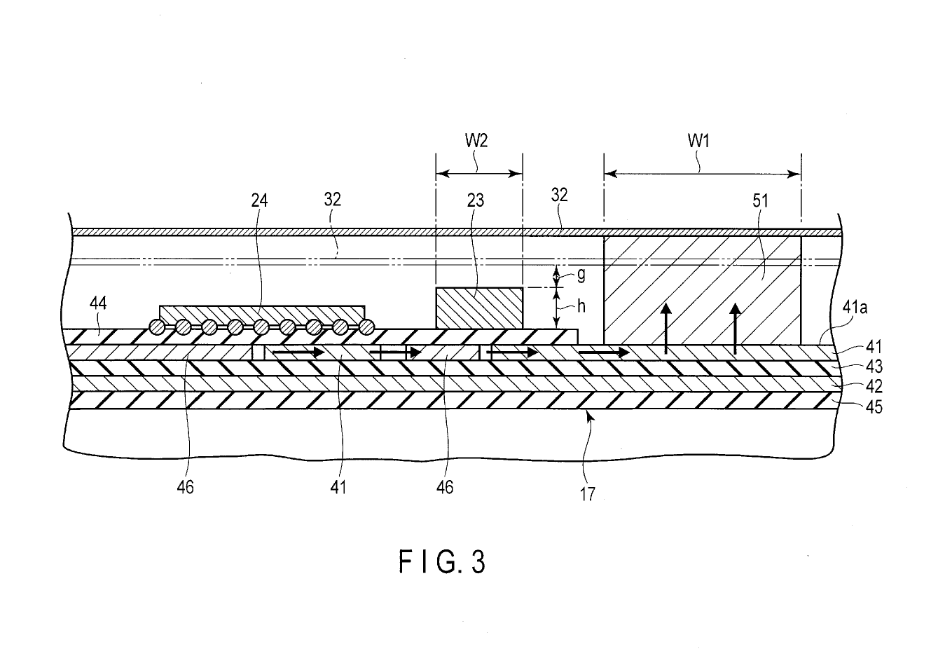

FIG. 3 is a schematically cross-sectional view of the circuit board 17 and the cover 32. The circuit board 17 comprises, for example, a first ground plane 41, a second ground plane 42, an insulating layer 43, a first cover layer 44 and a second cover layer 45. The first ground plane 41 and the second ground plane 42 are formed of, for example, a copper foil. The insulating layer 43 is positioned between the first ground plane 41 and the second ground plane 42. The insulating layer 43 is formed of, for example, glass epoxy resin, and electrically insulates the first ground plane 41 and the second ground plane 42 from each other.

In the present embodiment, the circuit board 17 comprises a power plane 46 (VCC) in the same layer as the first ground plane 41. The first ground plane 41 and the power plane 46 are electrically separated from each other. The circuit board 17 further comprises signal lines (trace patterns) electrically connected to the circuit components.

The first cover layer 44 is provided to cover the first ground plane 41, and is exposed on the surface of the circuit board 17. The second cover layer 45 is provided to cover the second ground plane 42, and is exposed on the surface of the circuit board 17.

As shown in FIG. 3, in the present embodiment, the first ground plane 41 comprises an exposed portion 41a exposed on the surface of the circuit board 17 near the heat-producing components 23 and 24. That is, a part of the first ground plane 41 is exposed to the outside of the circuit board 17 by providing a region without the first cover layer 44 near the heat-producing component 23 and 24 in the circuit board 17. A position where the exposed portion 41a is provided is not specified. For example, the exposed portion 41a may be provided near a component having a comparatively large heating value (for example, the power supply components 23 and 24) of components not having a dedicated radiative structure.

The first ground plane 41 is thermally coupled to the heat-producing component 23 and 24 via, for example, a pad or a via. At least a part of the heat from the heat-producing components 23 and 24 is thereby transmitted to the first ground plane 41. That is, the first ground plane 41 receives the heat from the heat-producing components 23 and 24. For example, the first ground plane 41 may be thermally coupled to all the circuit components including the CPU 21, the memory 22, the power supply components 23 and 24 and the electronic components 25.

The heat-producing components 23 and 24 include a first component 23 and a second component 24. The first component 23 and the second component 24 are different from each other in height (mounting height from the board surface). In the present embodiment, the first component 23 is taller than the second component 24. The first ground plane 41 is thermally coupled to the components different from each other in height and can receive the heat from these components at the same time. At least one of the first component 23 and the second component 24 is not limited to the power supply component but may be another component. That is, the first component 23 and the second component 24 may be components having the same function, and may be components having different functions.

As shown in FIG. 3, the cover 32 of the shield structure 30 covers the exposed portion 41a of the first ground plane 41 in addition to the plurality of circuit components as a whole. The cover 32 is an example of each of a metal member and a metal cover. A thermal coupling member 51 is provided between the exposed portion 41a of the first ground plane 41 and the inner surface of the cover 32. For example, the thermal coupling member 51 is a heat-transfer sheet (cooling sheet) and has predetermined elasticity.

The thermal coupling member 51 is sandwiched between the exposed portion 41a of the first ground plane 41 and the inner surface of the cover 32, and thermally couples the first ground plane 41 to the cover 32. Accordingly, at least a part of the heat from the heat-producing components 23 and 24 is transmitted to the cover 32 via the first ground plane 41 and the thermal coupling member 51, diffused along the surface of the cover 32, and thereby radiated inside the housing 2 from the cover 32.

As shown in FIG. 3, a width W1 of a contact portion of the thermal coupling member 51 and the first ground plane 41 is greater than a width W2 of at least one heat-producing component 23. In other words, the contact area of the thermal coupling member 51 and the first ground plane 41 is larger than the area of the top surface of at least one heat-producing component 23. As described above, a comparatively large thermal coupling member can be adopted and a comparatively large heat contact area can be secured by providing the thermal coupling member 51 in a position offset from the heat-producing components 23 and 24.

According to such a structure, the electronic apparatus 1 capable of improving the thermal radiation can be provided.

Recently, electronic apparatuses such as a notebook PC and a tablet are required to have a structure of efficiently radiating the heat of the system to the outside of the housing as the apparatuses become slimmer. A main heat-producing component such as a CPU arranged on the substrate has been required to be cooled. However, cooling components other than a main IC arranged on the substrate becomes important as the apparatuses become slimmer.

For comparison, for example, a structure of attaching a heat-transfer sheet having a certain thickness to a plurality of the heat-producing components is considered. In this case, since the components are largely different from each other in height, stress on the components can be increased in the structure of directly attaching the heat-transfer sheet to the components.

Therefore, in the present embodiment, the electronic apparatus 1 comprises the circuit board 17, the metal member (for example, the cover 32) and the thermal coupling member 51. The circuit board 17 comprises the first ground plane 41 thermally coupled to the heat-producing components 23 and 24 and exposed on the surface of the circuit board 17. The metal member covers the exposed portion 41a of the first ground plane 41. The thermal coupling member 51 is sandwiched between the exposed portion 41a of the first ground plane 41 and the metal member.

According to such a structure, for example, the heat of the circuit board 17 can be efficiently diffused in the metal member without imposing stress on the components different from each other in height. The thermal radiation of the electronic apparatus 1 can thereby be improved.

In the present embodiment, the metal member is a shield metal sheet which covers the circuit components mounted on the circuit board 17 as a whole. That is, in the present embodiment, the heat of the heat-producing component 23 and 24 can be efficiently diffused by using the shield metal sheet provided for the other purpose and having a comparatively large area. The thermal radiation of the electronic apparatus 1 can thereby be further improved.

In the present embodiment, the thermal coupling member 51 is provided not directly on the heat-producing component 23 and 24 but in the position offset from the heat-producing components 23 and 24. Therefore, the distance between the inner surface of the cover 32 and the heat-producing components 23 and 24 can be reduced in comparison with the case of providing the thermal coupling member 51 directly on the heat-producing components 23 and 24 (for example, see a modified embodiment drawn in double-dashed lines in FIG. 3). The shield structure 30 can thereby be slimmed. That is, according to the structure of the present embodiment, both the improvement in thermal radiation and the sliming of the electronic apparatus 1 can be achieved. In the above modified embodiment, a distance g between the inner surface of the cover 32 and the heat-producing component 23 is, for example, shorter than a height h of at least one heat-producing component 23.

A structure of sandwiching a thin thermal coupling member between the cover 32 and the heat-producing components 23 and 24 while reducing the distance between the inner surface of the cover 32 and the heat-producing components 23 and 24 is also considered. In such a structure, however, since the cover 32 and the heat-producing components 23 and 24 are physically in contact with each other via the thin thermal coupling member, the heat-producing components 23 and 24 are easily subject to impact from the cover 32 via the thermal coupling member, for example, when the impact is given from the outside.

In contrast, in the electronic apparatus 1 of the present embodiment, the thermal coupling member 51 is provided in the position offset from the heat-producing components 23 and 24. Therefore, the external impact hardly reaches the heat-producing components 23 and 24 since there is a space between the cover 32 and the heat-producing components 23 and 24 even if the distance between the cover 32 and the heat-producing components 23 and 24 is reduced. Therefore, according to the present embodiment, impact resistance and reliability of the electronic apparatus 1 can also be achieved in addition to the improvement in thermal radiation and the sliming.

According to the present embodiment, the thermal coupling member 51 is not directly in contact with the heat-producing components 23 and 24. Therefore, constraints such as hardness of the thermal coupling member 51 are small and it becomes possible to select a member superior in thermal conductivity, etc., from various thermal coupling members. Therefore, the thermal radiation of the electronic apparatus 1 can be further improved.

Electronic apparatuses 1 of second to fourth embodiments are hereinafter described. Structures having functions like or similar to the structures of the first embodiment are represented by the same reference numbers and their descriptions are omitted. Structures other than those hereinafter described are the same as the first embodiment.

### Second Embodiment

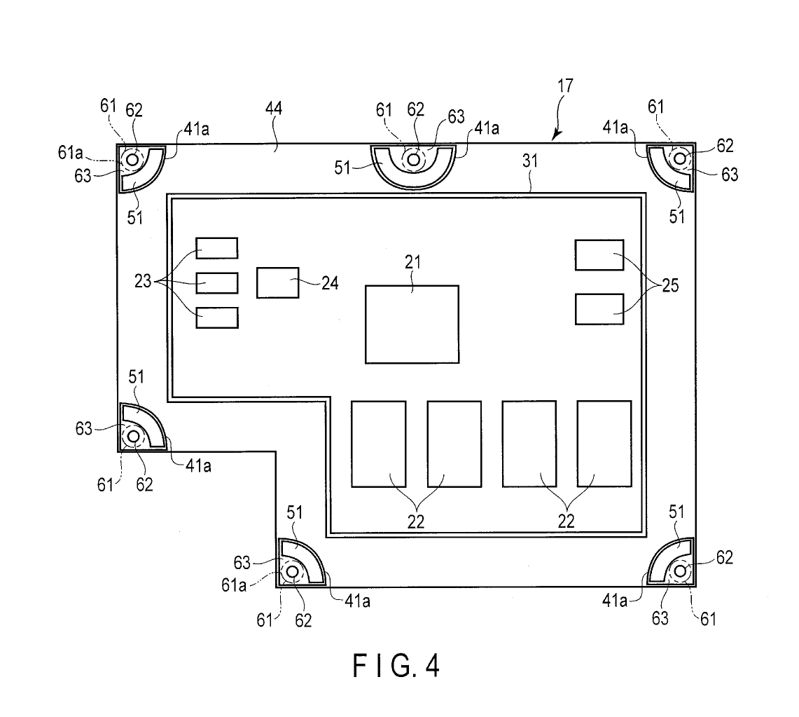

FIG. 4 is a plan view of a circuit board 17 of a second embodiment. An electronic apparatus 1 comprises screws 61 which fix the circuit board 17 to a housing 2. The screws 61 are examples of a fixing member. The circuit board 17 comprises insertion holes 62 into which the screws 61 are inserted. The insertion holes 62 are provided in the periphery of the circuit board 17, for example, at the corners of the circuit board 17 and the center of a side. The circuit board 17 also comprises ground portions 63 around the respective insertion holes 62. Each of the ground portions 63 is exposed on the surface of the circuit board 17 and, for example, faces a head 61a of each of the screws 61. The ground portions 63 are, for example, electrically connected to the ground of the housing 2 via the screws 61.

As shown in FIG. 4, in the present embodiment, exposed portions 41a of first ground planes 41 are provided integrally with the ground portions 63. That is, the exposed portions 41a of the first ground planes 41 are formed by extending the ground portions 63 in a radial direction of the screws 61. The shape of the exposed portions 41a of the first ground planes 41 is not specified. For example, the exposed portions 41a may have a sector or semicircular shape along the circumference of the screws 61.

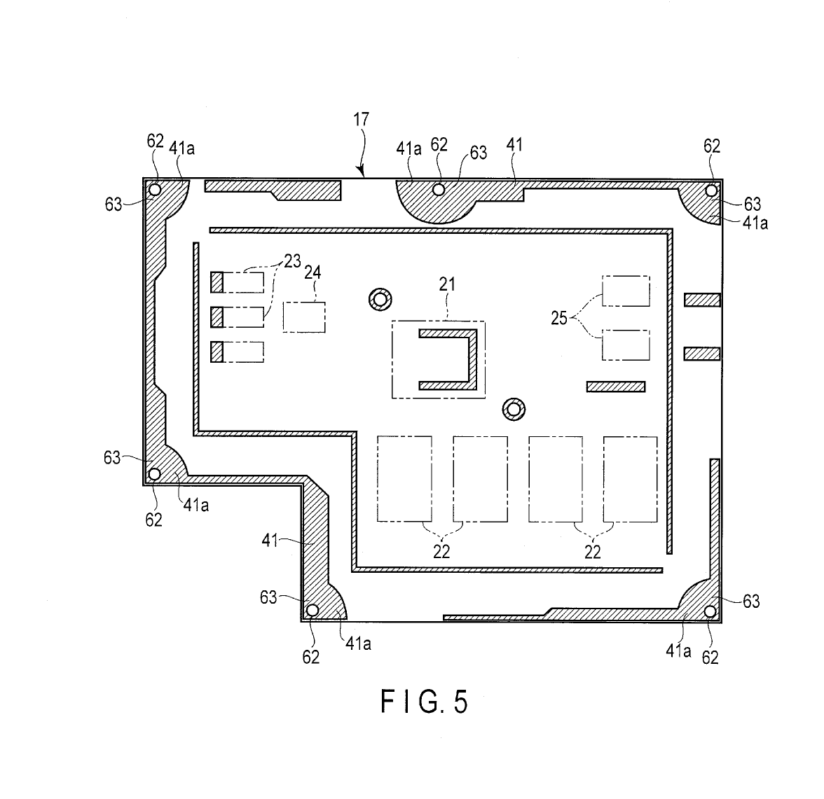

For convenience of description, FIG. 5 exemplarily shows an arrangement of the first ground planes 41 in a case where the first cover layer 44 is removed. For convenience of description, the first ground planes 41 are hatched in FIG. 5. The first ground planes 41 shown in FIG. 5 are electrically and thermally coupled to each other via an inner layer of the circuit board 17 or a second ground plane 42.

A number of power planes 46 of the circuit board 17 are provided, for example, in the center region of the circuit board 17. A number of first ground planes 41 are provided near the periphery of the circuit board 17 in comparison with the power planes 46, and some of them are extended along the periphery of the circuit board 17.

For this reason, the area of the exposed portions 41 of the first ground planes 41 is easily secured in the periphery of the circuit board 17. If the large area for the exposed portions 41a of the first ground planes 41 can be secured, the contact area of the thermal coupling members 51 and the first ground planes 41 can be increased, and the first ground planes 41 and the cover 32 can be thermally coupled to each other more strongly.

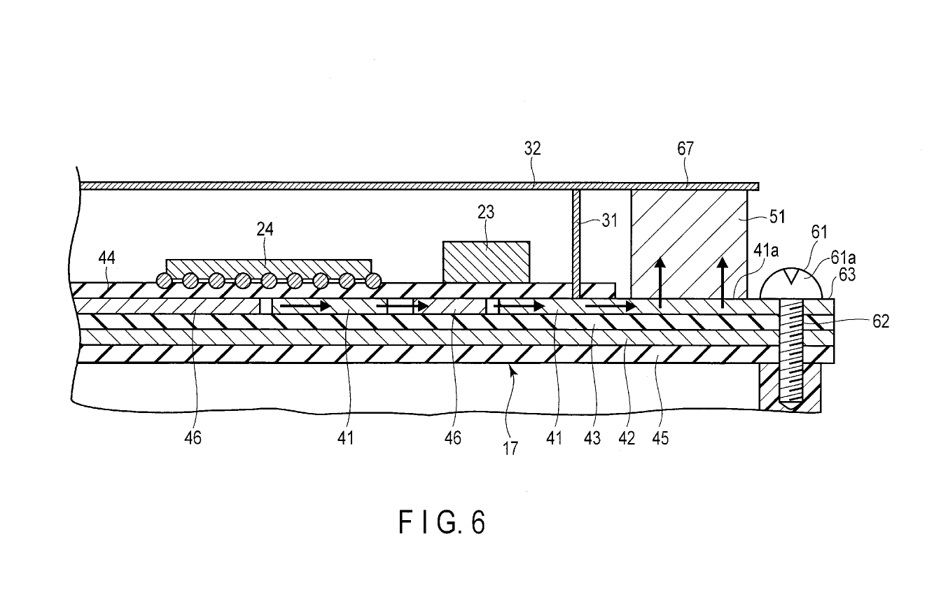

As shown in FIG. 4, the thermal coupling members 51 have, for example, a sector or semicircular shape along the circumference of the screws 61. However, the shape of the thermal coupling members 51 is not limited to this. FIG. 6 is a cross-sectional view of the circuit board 17 and the cover 32 of the present embodiment. In the present embodiment, the cover 32 may comprise, for example, an extended portion 67 extended to the outside of the frame 31. The thermal coupling member 51 is sandwiched between, for example, the circuit board 17 and the extended portion 67 of the cover 32.

According to the electronic apparatus 1 of such a structure, the thermal radiation can be improved similarly to the first embodiment. In the present embodiment, the circuit board 17 further comprises the insertion holes 62 into which the screws 61 are inserted, and the ground portions 63 provided around the insertion holes 62. The exposed portions 41a of the first ground planes 41 are provided integrally with the ground portions 63. According to such a structure, the large exposed portions 41a of the first ground planes 41 are easily secured in the circuit board 17 of which area is limited.

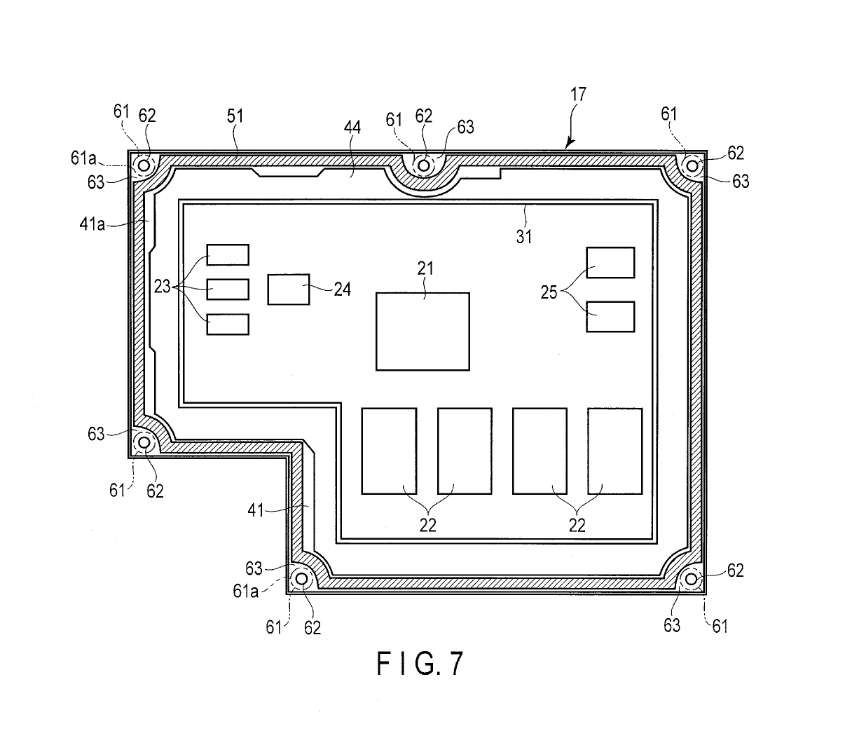

In the present embodiment, the exposed portions 41a of the first ground planes 41 and the thermal coupling members 51 are provided along at least a part of the periphery of the circuit board 17. According to such a structure, a comparatively large contact area of the first ground plane 41 and the thermal coupling member 51 can be secured as described above. As shown in FIG. 7, the thermal coupling member 51 may be formed, for example, in a frame shape along the periphery of the circuit board 17. For convenience of description, the thermal coupling member 51 is hatched in FIG. 7.

### Third Embodiment

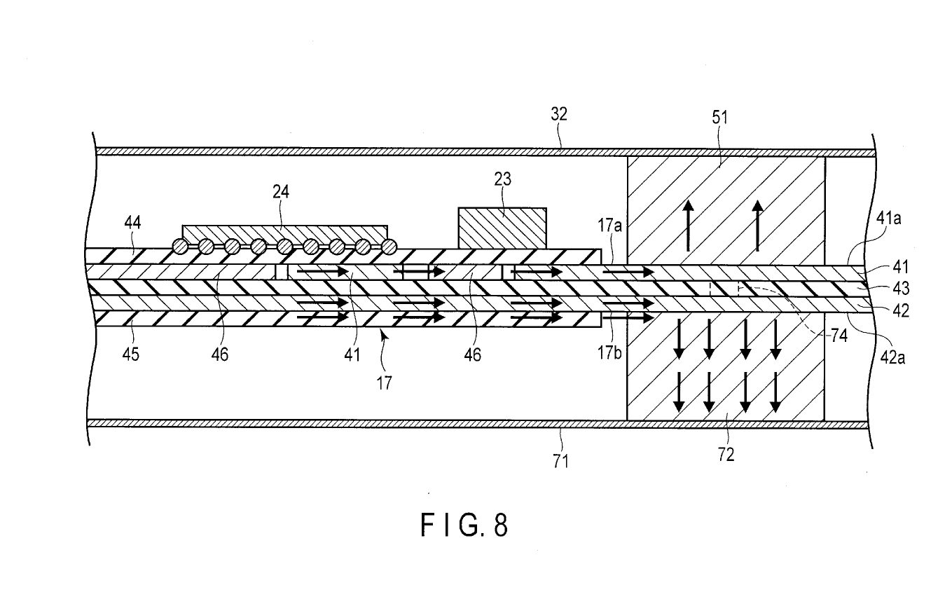

FIG. 8 is a cross-sectional view of a circuit board 17 and a cover 32 of a third embodiment. An electronic apparatus 1 of the present embodiment comprises a second cover 71 and a second thermal coupling member 72 in addition to the structure of the first embodiment. For convenience of description, structures having functions like or similar to the cover 32 and thermal coupling member 51 of the first embodiment are referred to as a first cover 32 and a first thermal coupling member 51, respectively, and their descriptions are omitted.

As shown in FIG. 8, the circuit board 17 comprises a first surface 17a and a second surface 17b positioned on the opposite side of the first surface 17a. An exposed portion 41a of a first ground plane 41 is exposed on the first surface 17a of the circuit board 17. A second ground plane 42 comprises an exposed portion 42a exposed on the second surface 17b of the circuit board 17.

The second cover 71 covers the exposed portion 42a of the second ground plane 42 and other portions of the circuit board 17 as a whole. The second cover 71 has approximately the same structure and function as the first cover 32. The second cover 71 is, for example, a shield metal sheet against EMI, i.e., an example of each of a second metal member and a second metal cover. The second ground plane 42 is thermally coupled to heat-producing components 23 and 24. For example, the second ground plane 42 may be thermally coupled to all circuit components including a CPU 21, a memory 22, the power supply components 23 and 24 and electronic components 25.

The second thermal coupling member 72 is sandwiched between the exposed portion 42a of the second ground plane 42 and the inner surface of the second cover 71. For example, the second thermal coupling member 72 is a heat-transfer sheet (cooling sheet) and has predetermined elasticity. The second thermal coupling member 72 thermally couples the second ground plane 42 to the second cover 71. Therefore, at least a part of the heat from the heat-producing components 23 and 24 is transmitted to the second cover 71 via the second ground plane 42 and the second thermal coupling member 72, diffused along the surface of the second cover 71, and thereby radiated inside a housing 2 from the second cover 71.

According to such a structure, the thermal radiation of the electronic apparatus 1 can be improved in a similar manner to the first embodiment. In the present embodiment, the electronic apparatus 1 further comprises the second metal member (for example, the second cover 71) and the second thermal coupling member 72. The circuit board 17 comprises the first surface 17a on which the first ground plane 41 is exposed, and the second surface 17b on which the second ground plane 42 is exposed. The second metal member covers the exposed portion 42a of the second ground plane 42. The second thermal coupling member 72 is sandwiched between the exposed portion 42a of the second ground plane 42 and the second metal member. According to such a structure, the heat of the circuit board 17 can be efficiently diffused by the two metal members. The thermal radiation of the electronic apparatus 1 can thereby be further improved.

As shown in FIG. 8, the first thermal coupling member 51 and the second thermal coupling member 72 overlap each other in a thickness direction of the circuit board 17. According to such a structure, the ground planes can be gathered in the circuit board 17, and the exposed portion 41a of the first ground plane 41 and the exposed portion 42a of the second ground plane 42 can be easily formed. Furthermore, according to such a structure, even if the circuit board 17 warps owing to the installation of the thermal coupling members 51 and 72, the warp can be reduced. This contributes to the improvement of reliability of the electronic apparatus 1.

Next, heat-transfer characteristics of the first thermal coupling member 51 and the second thermal coupling member 72 are described.

In the present embodiment, the second thermal coupling member 72 is formed of, for example, a material different from the first thermal coupling member 51 in thermal conductivity. An amount of heat flowing through the second cover 71 can be greater than an amount of heat flowing through the first cover 32 by, for example, forming the second thermal coupling member 72 of a material having thermal conductivity higher than that of the first thermal coupling member 51. The amount of heat flowing through the first cover 32 can be greater than the amount of heat flowing through the second cover 71 by forming the first thermal coupling member 51 of a material having a thermal conductivity higher than that of the second thermal coupling member 72. The amount of heat diffused in the top and under surfaces of the circuit board 17 can thereby be distributed, and temperature control of the housing 2 can be facilitated.

An example of application of such temperature control is described. The electronic apparatus 1 of the present embodiment comprises the housing 2 accommodating the circuit board 17, the first cover 32 and the second cover 71. The housing 2 comprises a front wall 11 on which a display 3 is exposed, and a back wall 12 positioned on the opposite side of the front wall 11. For example, the user can use the electronic apparatus 1 in hand. When the user holds the electronic apparatus 1 by hand, the user's hand touches the back wall 12 more frequently than or over a larger area than that of the front wall 11.

One of the first cover 32 and the second cover 71 faces the inner surface of the back wall 12 of the housing 2. The other one of the first cover 32 and the second cover 71 faces the inner surface of the front wall 11 of the housing 2. The first thermal coupling member 51 and the second thermal coupling member 72 are, for example, formed of materials different from each other in thermal conductivity such that the temperature of one of the first cover 32 and the second cover 71 facing the back wall 12 of the housing 2 is lower than the temperature of the other one of the first cover 32 and the second cover 71 facing the inner surface of the front wall 11 of the housing 2.

For example, in the present embodiment, the first cover 32 faces the inner surface of the back wall 12 of the housing 2. The second cover 71 faces the inner surface of the front wall 11 of the housing 2. Therefore, the second thermal coupling member 72 is formed of a material having a thermal conductivity higher than that of the first thermal coupling member 51 such that the temperature of the first cover 32 is lower than the temperature of the second cover 71 (in other words, a greater amount of heat flows from the circuit board 17 to the second cover 71 in comparison with the first cover 32). A rise in temperature of the back wall 12 of the housing 2 touched by the user's hand more frequently than the front wall 11 can thereby be avoided.

The second thermal coupling member 72 may be formed of a material having the thermal conductivity different from the first thermal coupling member 51, not only for the purpose of avoiding a rise in temperature of the wall frequently touched by the user's hand, but also for various purposes. For example, the first thermal coupling member 51 and the second thermal coupling member 72 may be formed of materials different from each other in thermal conductivity for the purpose of reducing the temperature difference between the first cover 32 and the second cover 71. According to such a structure, the imbalance between the amount of heat flowing through the first cover 32 and the amount of heat flowing through the second cover 71 can be redressed and the thermal radiation of the electronic apparatus 1 can be further improved.

For example, in the present embodiment, the electronic apparatus 1 comprises a thermal coupling member 35 which transmits the heat of the CPU 21 (main heat-producing component) to the first cover 32 (FIG. 2). The second thermal coupling member 72 is formed of a material having a thermal conductivity higher than that of the first thermal coupling member 51. The heat of the heat-producing components 23 and 24 can thereby efficiently escape to the second cover 71 different from the first cover 32 of which temperature is easily increased by the heat from the main heat-producing component. The thermal radiation of the electronic apparatus 1 can thereby be further improved.

As shown in FIG. 8, the circuit board 17 may comprise a via 74 (interlayer thermal coupling portion) which provides thermal coupling between the first ground plane 41 and the second ground plane 42. If such a via 74 is provided, the temperature control of the housing 2 is further facilitated. The heat of the first ground plane 41 can efficiently escape to the second cover 71 by providing the via 74.

In the present embodiment, the via 74 is provided in a position overlapping both the first thermal coupling member 51 and the second thermal coupling member 72 in the thickness direction of the circuit board 17. If the via 74 is provided in such a position, the temperature control of the housing 2 is further facilitated.

Next, some modified embodiments of the present embodiment are described.

### First Modified Embodiment

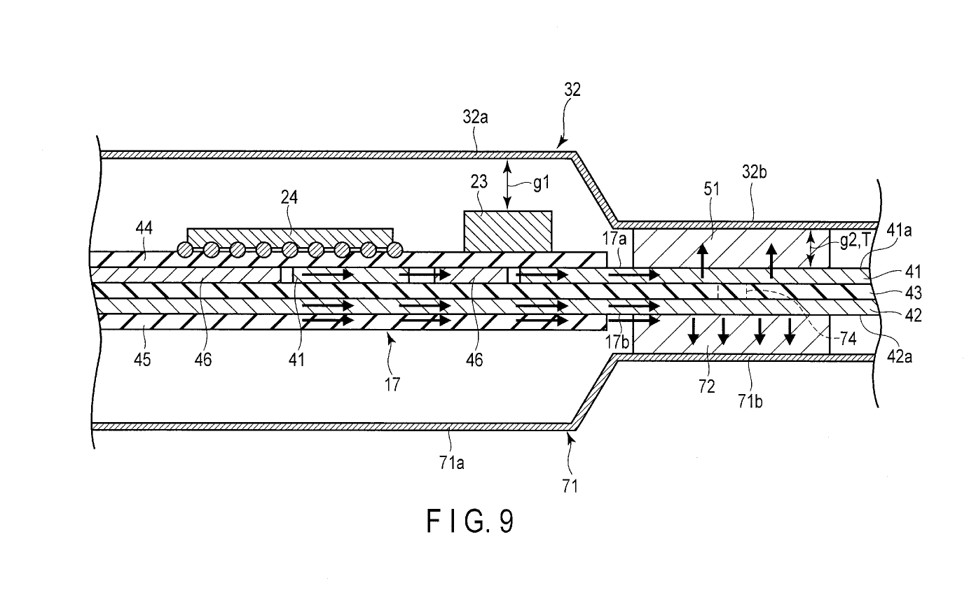

FIG. 9 is a cross-sectional view of a circuit board 17 and covers 32 and 71 of a first modified embodiment of the third embodiment. The first cover 32 comprises a first region 32a facing heat-producing components 23 and 24, and a second region 32b facing an exposed portion 41a of a first ground plane 41. The second region 32b is bent from the first region 32a to the circuit board 17 and positioned closer to the circuit board 17 than the first region 32a. A first thermal coupling member 51 is sandwiched between the circuit board 17 and the second region 32b of the first cover 32.

Similarly, the second cover 71 comprises a first region 71a positioned on the back side of the heat-producing components 23 and 24, and a second region 71b facing an exposed portion 42a of a second ground plane 42. The second region 71b is bent from the first region 71a to the circuit board 17 and positioned closer to the circuit board 17 than the first region 71a. A second thermal coupling member 72 is sandwiched between the circuit board 17 and the second region 71b of the second cover 71.

According to such a structure, the distance between the first cover 32 and the exposed portion 41a of the first ground plane 41 can be reduced and a thickness T of the first thermal coupling member 51 can be also reduced. The thermal resistance between the first ground plane 41 and the first cover 32 can thereby be reduced, and the thermal radiation of the electronic apparatus 1 can be further improved. If the first cover 32 is formed of, for example, a metal sheet, a level difference between the first region 32a and the second region 32b can be easily formed by bending. Even if the second region 32b of the first cover 32 is positioned close to the circuit board 17, constraints on a total thickness of the electronic apparatus 1 is not increased. On the contrary, the electronic apparatus 1 can be further slimmed. Since a material of the thermal coupling member 51 can be reduced, the cost of the electronic apparatus 1 can be cut down. The same structure can also be applied to the second cover 71 and the second thermal coupling member 72.

In the present embodiment, a distance g2 between the circuit board 17 and the second region 32b of the first cover 32 (i.e., the thickness T of the first thermal coupling member 51) is shorter than a distance g1 between the heat-producing component 23 and the first region 32a of the first cover 32. According to such a structure, the thickness T of the first thermal coupling member 51 can be further reduced and the thermal resistance between the first ground plane 41 and the first cover 32 can also be further reduced.

### Second Modified Embodiment

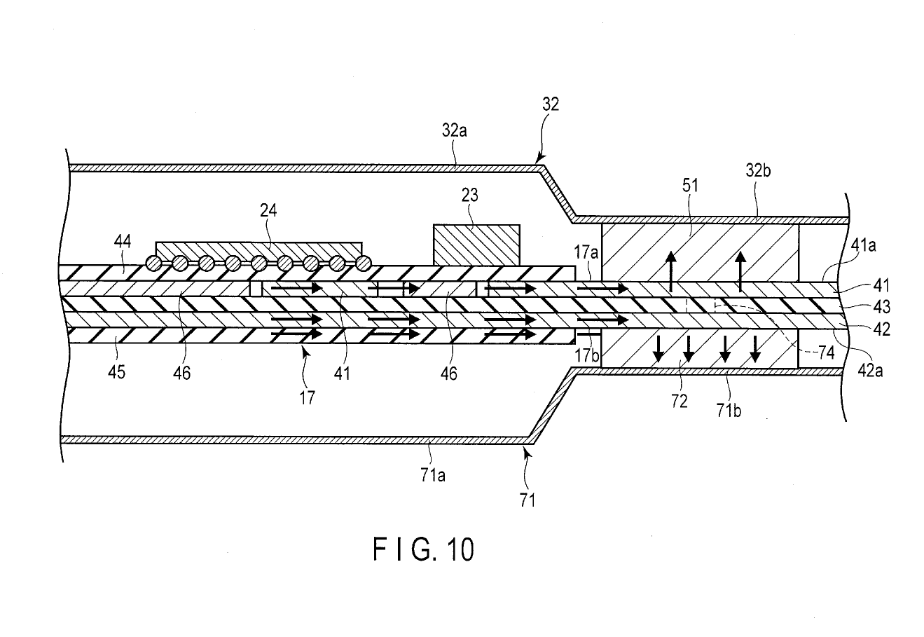

FIG. 10 is a cross-sectional view of a circuit board 17 and covers 32 and 71 of a second modified embodiment of the third embodiment. In the present modified embodiment, a first thermal coupling member 51 and a second thermal coupling member 72 are formed of a material having the same thermal conductivity. In the present modified embodiment, an amount of heat diffused in the top and under surfaces of the circuit board 17 can be distributed and the temperature of a housing 2 can be controlled by making a difference in thickness between the first thermal coupling member 51 and the second thermal coupling member 72.

An example of application of such temperature control of the housing 2 is described. The first thermal coupling member 51 and the second thermal coupling member 72 are different from each other in thickness such that the temperature of one of the first cover 32 and the second cover 71 facing a back wall 12 of the housing 2 is lower than the temperature of the other one of the first cover 32 and the second cover 71 facing a front wall 11, similarly to the first modified embodiment. For example, an amount of heat flowing through the second cover 71 can be greater than an amount of heat flowing through the first cover 32 by making the second thermal coupling member 72 thinner than the first thermal coupling member 51. The amount of heat flowing through the first cover 32 can be greater than the amount of heat flowing through the second cover 71 by making the first thermal coupling member 51 thinner than the second thermal coupling member 72.

For example, in the present embodiment, the first cover 32 faces the inner surface of the back wall 12 of the housing 2. The second cover 71 faces the inner surface of the front wall 11 of the housing 2. Therefore, a distance between a second region 32b of the first cover 32 and the circuit board 17 is made longer than a distance between a second region 71b of the second cover 71 and the circuit board 17, and the first thermal coupling member 51 is made thicker than the second thermal coupling member 72. A rise in temperature of the back wall 12 of the housing 2 touched by the user's hand more frequently than the front wall 11 can thereby be avoided.

The difference in thickness may be made between the first thermal coupling member 51 and the second thermal coupling member 72 not only for the purpose of avoiding a rise in temperature of the wall frequently touched by the user's hand, but also for various purposes. For example, the first thermal coupling member 51 and the second thermal coupling member 72 may be different from each other in thickness for the purpose of reducing the temperature difference between the first cover 32 and the second cover 71.

For example, in the present modified embodiment, the electronic apparatus 1 comprises a thermal coupling member 35 which transmits the heat of a CPU 21 (main heat-producing component) to the first cover 32 (FIG. 2). The second thermal coupling member 72 is formed to be thinner than the first thermal coupling member 51. The heat of the heat-producing components 23 and 24 can thereby efficiently escape to the second cover 71 different from the first cover 32 of which temperature is easily increased by heat from the main heat-producing component.

### Third Modified Embodiment

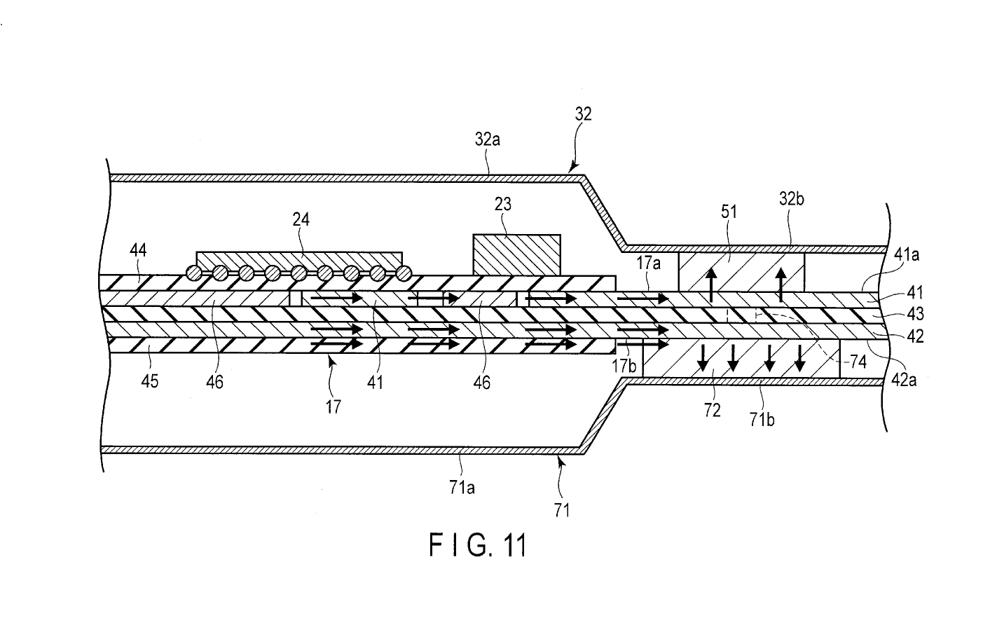

FIG. 11 is a cross-sectional view of a circuit board 17 and covers 32 and 71 of a third modified embodiment of the third embodiment. In the present modified embodiment, a first thermal coupling member 51 and a second thermal coupling member 72 are formed of a material having the same thermal conductivity. In the present modified embodiment, the temperature can be controlled as in the second modified embodiment by making a difference in area between the first thermal coupling member 51 and the second thermal coupling member 72. The technical meaning of the area of the thermal coupling member being large corresponds to the thermal coupling member being thin. Therefore, the temperature of a housing 2 can be controlled for various purposes similarly to the second modified embodiment by making a difference in area between the first thermal coupling member 51 and the second thermal coupling member 72.

### Fourth Embodiment

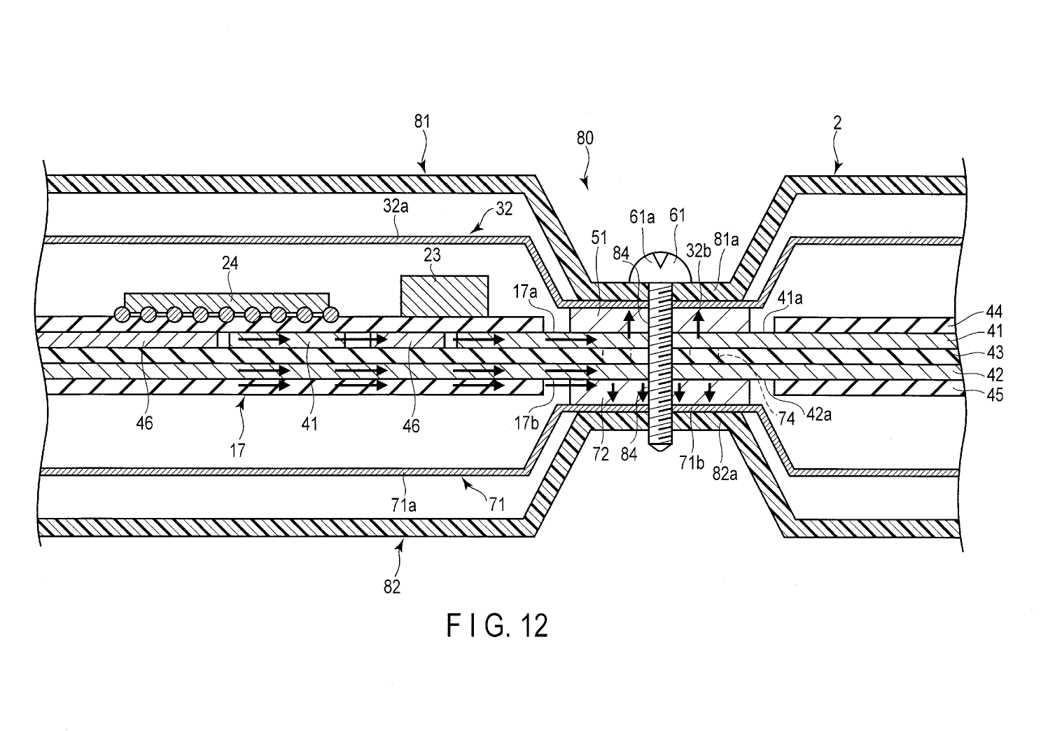

FIG. 12 is a cross-sectional view of an electronic apparatus 1 of a fourth embodiment. In the electronic apparatus 1 of the present embodiment, thermal coupling members 51 and 72 are sandwiched in the fastening portion 80 which fastens a housing 2, covers 32 and 71 and a circuit board 17.

More specifically, the housing 2 comprises a first housing member 81 and a second housing member 82. The first housing member 81 covers the first cover 32 and comprises a first fixing portion 81a. The first fixing portion 81a is recessed toward the circuit board 17 and is in contact with the first cover 32. The second housing member 82 covers the second cover 71 and comprises a second fixing portion 82a. The second fixing portion 82a is recessed toward the circuit board 17 and is in contact with the second cover 71.

The electronic apparatus 1 comprises a screw 61 which fixes the first housing member 81, the second housing member 82, the first cover 32, the second cover 71 and the circuit board 17 as a whole. Each of the first thermal coupling member 51 and the second thermal coupling member 72 has a through-hole 84 through which the screw 61 penetrates, and is provided around the screw 61. That is, the first thermal coupling member 51 and the second thermal coupling member 72 are provided in the fastening portion 80 of the housing 2, and the screw 61 penetrates the members. The first thermal coupling member 51 is pressed against the first ground plane 41 and the second thermal coupling member 72 is pressed against the second ground plane 42 by tightening the screw 61.

According to such a structure, the thermal radiation of the electronic apparatus 1 can be improved in a similar manner to the first embodiment. In the present embodiment, the electronic apparatus 1 comprises the screw 61 which fixes the metal member (for example, the first cover 32) and the circuit board 17. The first thermal coupling member 51 comprises the through-hole 84 through which the screw 61 penetrates, is provided around the screw 61, and is pressed against the first ground plane 41 by tightening the screw 61. According to such a structure, the first thermal coupling member 51 is attached by using the fixation structure of the metal member. In the present embodiment, the first thermal coupling member 51 is attached by using the fastening portion 80 of the housing 2. According to such structures, the mounting area of the circuit board 17 can be efficiently used in comparison with a case of providing the first thermal coupling member 51 in another region in the circuit board 17. This contributes to miniaturization of the electronic apparatus 1. Furthermore, if the first thermal coupling member 51 can be pressed against the first ground plane 41 by using the screw 61 fixing the metal member and the circuit board, the thermal coupling between the first thermal coupling member 51 and the first ground plane 41 becomes stronger. The thermal radiation of the electronic apparatus 1 can thereby be further improved.

The first to fourth embodiments and their modified embodiments have been described, but the structure is not limited to these embodiments and modified embodiments. The structures of the first to fourth embodiments and their modified embodiments can be applied in combination with each other. For example, the first thermal coupling member 51 and the second thermal coupling member 72 may be different from each other in material, thickness, area, etc., in the fourth embodiment. The metal member (first metal member) and the second metal member are not limited to the covers 32 and 71 of the shield structure 30, but may be, for example, the housing 2 (for example, a metal first housing member 81 and a metal second housing member 82) of the electronic apparatus 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a circuit board comprising a heat-producing component and a first ground sheet thermally coupled to the heat-producing component, the first ground sheet comprising an exposed portion on a surface of the circuit board;
a first metal member covering the exposed portion of the first ground sheet; and
a first thermal coupling member between the exposed portion of the first ground sheet and the first metal member.

2. The apparatus of claim 1, further comprising a housing comprising the circuit board and the first metal member,
wherein the first metal member is a shield metal sheet positioned between the circuit board and an inner surface of the housing and covers an entirety of the circuit board comprising a plurality of circuit components mounted on the circuit board.

3. The apparatus of claim 2, wherein
the shield metal sheet comprises a first region facing the heat-producing component and a second region, the second region connected to the first region closer to the circuit board than the first region, and
the first thermal coupling member between the circuit board and the second region of the shield metal sheet.

4. The apparatus of claim 3, wherein a distance between the circuit board and the second region of the shield metal sheet is shorter than a distance between the heat-producing component and the first region of the shield metal sheet.

5. The apparatus of claim 1, wherein
the circuit board comprises an insertion hole into which a screw is inserted, and a ground portion around the insertion hole, and
the exposed portion of the first ground sheet is integrated with the ground portion.

6. The apparatus of claim 5, wherein
the screw fixes the first metal member and the circuit board, and
the first thermal coupling member comprises a through-hole into which the screw is inserted, wherein the first thermal coupling member is pressed against the first ground sheet by fastening the screw.

7. The apparatus of claim 6, further comprising a housing comprising the circuit board and the first metal member,
wherein the screw fixes the housing, the first metal member and the circuit board together.

8. The apparatus of claim 1, wherein
the exposed portion of the first ground sheet and the first thermal coupling member are along at least a part of a periphery of the circuit board.

9. The apparatus of claim 1, further comprising a second metal member and a second thermal coupling member,
wherein the circuit board comprises a first surface on which the first ground sheet is exposed, a second surface positioned on an opposite side of the first surface, and a second ground sheet comprising an exposed portion on the second surface,
the second metal member covers the exposed portion of the second ground sheet, and
the second thermal coupling member is between the exposed portion of the second ground sheet and the second metal member.

10. The apparatus of claim 9, wherein
the second thermal coupling member comprises a material different from the first thermal coupling member in thermal conductivity.

11. The apparatus of claim 9, further comprising a housing comprising the circuit board, the first metal member, the second metal member, a front wall on which a display screen is exposed and a back wall positioned on an opposite side of the front wall,
wherein the first thermal coupling member and the second thermal coupling member comprise materials different from each other in thermal conductivity such that a temperature of one of the first metal member and the second metal member facing the back wall is lower than a temperature of the other facing the front wall.

12. The apparatus of claim 9, further comprising a housing comprising the circuit board, the first metal member, the second metal member, comprising a front wall on which a display screen is exposed and a back wall positioned on an opposite side of the front wall,
wherein the first thermal coupling member and the second thermal coupling member are different from each other in thickness and/or in area such that a temperature of one of the first metal member and the second metal member facing the back wall is lower than a temperature of the other facing the front wall.

13. The apparatus of claim 9, wherein the first thermal coupling member and the second thermal coupling member comprise materials different from each other in thermal conductivity such that the temperature difference between the first metal member and the second metal member is reduced.

14. The apparatus of claim 9, wherein the first thermal coupling member and the second thermal coupling member are different from each other in thickness and/or in area such that a temperature difference between the first metal member and the second metal member is reduced.

15. The apparatus of claim 9, further comprising:
a main heat-producing component on the first surface of the circuit board; and
a third thermal coupling member which transmits heat of the main heat-producing component to the first metal member,
wherein the second thermal coupling member comprises a thermal conductivity higher than a thermal conductivity of the first thermal coupling member.

16. The apparatus of claim 9, further comprising:
a main heat-producing component on the first surface of the circuit board; and
the third thermal coupling member which transmits heat of the main heat-producing component to the first metal member,
wherein the second thermal coupling member is larger in area or thinner than the first thermal coupling member.

17. The apparatus of claim 9, wherein the circuit board comprises a via for thermal coupling between the first ground sheet and the second ground sheet.

18. The apparatus of claim 17, wherein the via is in a position overlapping both the first thermal coupling member and the second thermal coupling member in a thickness direction of the circuit board.
